(19) United States
(12) Patent Application Publication
(10) Pub. No.: US 2025/0151237 A1
(43) Pub. Date: May 8, 2025

(54) HOUSING FOR AN ELECTRIC OR ELECTRONIC DEVICE

(71) Applicant: HELLA GMBH & CO. KGAA, Lippstadt (DE)

(72) Inventors: Frank Brinkmeier, Lippstadt (DE); Christoph Seeberg-Elverfeldt, Wadersloh (DE); Thomas Wiese, Lippstadt (DE); Oleksandr Kalytenko, Lippstadt (DE)

(21) Appl. No.: 19/011,790

(22) Filed: Jan. 7, 2025

Related U.S. Application Data
(63) Continuation of application No. PCT/EP2023/068248, filed on Jul. 3, 2023.

(30) Foreign Application Priority Data
Jul. 11, 2022 (DE) 102022117193.0

(51) Int. Cl. H05K 7/20; H05K 5/04; H05K 9/00

(52) U.S. Cl. CPC H05K 7/2039; H05K 5/04; H05K 9/0049

(57) ABSTRACT

The invention relates to a housing for an electric or electronic device. The housing includes a housing lower part, which is made of metal and is designed as a heat sink for dissipating heat generated by the device. At least two rivet pins are formed in one piece with the housing lower part. The housing includes at least one circuit board on which the device is formed in the form of electric and/or electronic components and conductor tracks. The circuit board is mounted in the housing lower part. The housing also includes a shielding plate for shielding against electromagnetic radiation and a housing upper part for closing the housing. The housing lower part, the circuit board, the shielding plate, and the housing upper part are sealingly connected to one another by forming rivet heads on the rivet pins.

### CROSS-REFERENCE TO RELATED APPLICATIONS

The present application is a continuation of International Application No. PCT/EP2023/068248, filed Jul. 3, 2023, which claims priority to German Patent Application 10-2022-117-193.0, filed Jul. 11, 2022, the disclosures of which are incorporated by reference.

### FIELD OF THE INVENTION

The invention relates to a housing for an electric or electronic device. The housing includes a housing lower part which is made of metal and is designed as a heat sink for dissipating heat generated by the device. At least two rivet pins are formed integrally with the housing lower part. The housing includes at least one circuit board on which the device is formed in the form of electric and/or electronic components and conductor traces and which is mounted in the housing lower part. The housing also includes a shielding plate for shielding electromagnetic radiation and a housing upper part for closing the housing.

### BACKGROUND OF THE INVENTION

Housings are well known and are used, for example, in motor vehicles for protecting and mounting a control apparatus.

DE10062699A1 describes a cooling device for a control apparatus that can be mounted on a housing of the control apparatus. The cooling apparatus is made of thin sheet metal by deep drawing. It has nubs that penetrate the assigned through-holes of the housing and, through deformation, create a frictional connection with the assigned through-hole and thus a fixed connection between the housing and the cooling apparatus.

WO2014/095171A1 discloses a housing of a control apparatus in which a separate convector is arranged on an outer side as a cooling apparatus, which is thermally and mechanically connected to the housing. The connection can be made by riveting, wherein a circuit board can be mounted at the same time.

It is the object of the invention to create a housing for an electric or electronic device which is simple and inexpensive to manufacture.

### SUMMARY OF THE INVENTION

The foregoing object is achieved by the embodiments of the present invention. The housing lower part, the circuit board, the shielding plate, and the housing upper part are sealingly connected to one another by forming rivet heads on the rivet pins. This makes it possible to ensure the required hold for all parts to be mounted on the housing lower part using a common mounting means. In this case, the rivet pins are formed in one piece with the housing lower part, so that fewer parts—e.g. no screws or separate rivets-need to be handled overall. The rivet heads can be formed simultaneously for everyone without a great deal of effort. This makes the electric or electronic device easier and cheaper to manufacture overall. Rivets also have the advantage over screws that they require less overall height of the housing because the domes or cups required for mounting the screws are no longer necessary.

In one embodiment, the rivet pin is designed as a hollow pin with a closed upper end. This facilitates the formation of the rivet head and the sealing connection of the parts of the device.

In a further embodiment, the rivet pin has a circular cross-section with a maximum diameter of 5 mm. This also means that the rivet head is correspondingly small, saving surface on the circuit board that can be used for assembly; or the circuit board can have a smaller surface.

In a further embodiment, the housing lower part is made of an aluminum alloy. This has good thermal conductivity, can be easily formed to form the rivet heads and is lightweight.

In a further embodiment, the circuit board is galvanically connected to the housing lower part and the shielding plate. This provides particularly good electromagnetic shielding.

In a further embodiment, the rivet pins are formed by deep drawing. This is possible to implement in terms of production technology, e.g. by implementing it in a progressive die for an automatic punching press.

### BRIEF DESCRIPTION OF THE DRAWING

The invention is explained in more detail below with reference to the attached schematic drawing. In the figures:

FIG. 1 shows a top view of an electric or electronic apparatus;

FIG. 2a shows a section through an area around a rivet before riveting; and

FIG. 2b shows a section through an area around a rivet after riveting.

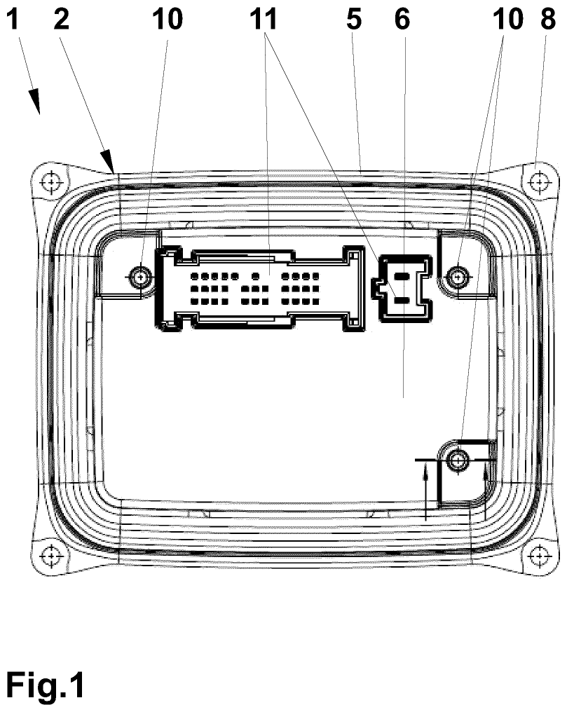

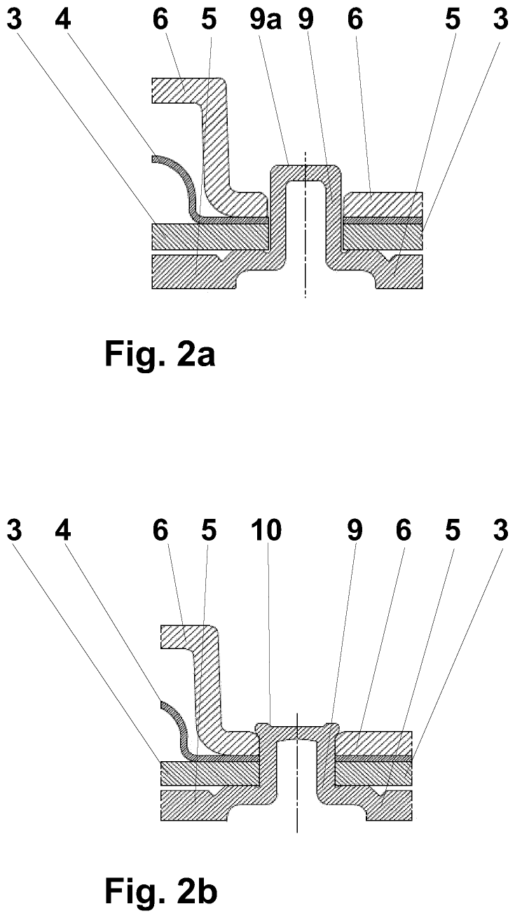

### DETAILED DESCRIPTION OF THE CURRENT EMBODIMENT

As can be seen from the figures, an electric or electronic device 1 comprises a housing 2 including a circuit board 3 and a shielding plate 4.

The housing 2 is formed from a trough-shaped housing lower part 5 and a lid-like housing upper part 6.

The housing lower part 5 is substantially rectangular here in a plan view, is made of an aluminum alloy and has, for example, a plurality of cooling fins on its underside as a heat sink. The housing lower part 5 has a mounting lug 8 on the outside of each corner for mounting the device 1 on a motor vehicle body, for example. Inside a trough part of the housing lower part 5, a support surface is formed in each of the four corner areas to support the circuit board 3. A rivet pin 9 projects perpendicularly to the contact surface upwards into the interior of the housing lower part 5. The rivet pin 9 has an annular cross-section and is closed at its free end 9A, i.e. the end pointing upwards away from the contact surface; the rest of the rivet pin 9 is hollow on the inside.

The circuit board 3 is inserted into the housing lower part 5 in such a manner that the rivet pins 9 penetrate the through holes in its corner regions. The circuit board 3 is equipped as usual with conductor traces and electric and/or electronic components. Furthermore, at least one socket 11 is arranged on an upper surface of the circuit board facing the housing upper part 6 in order to be able to connect the device 1 to an on-board electronic system by means of a corresponding plug and cable. The circuit board 3 has a conductive surface in its corner areas, both on the top side and on the underside.

At least part of the components arranged on the upper side of the circuit board 3 is covered by the shielding plate 4 at a distance, wherein a recess corresponding to the socket 11 is provided in the shielding plate 4. Like the circuit board, the shielding plate 4 has through-holes in its corner areas, which are penetrated by the rivet pins 9.

The housing lower part 5 is covered by the housing upper part 6, wherein the socket 11 penetrates the housing upper part 6. The rivet pins 9 also penetrate corresponding through-holes in the housing upper part 6. This is preferably made of plastic.

After the housing lower part 5, the circuit board 3, the shielding plate 4 and the housing upper part 6 have been assembled, the rivet pins 9 are formed using pressing tools. On the one hand, a rivet head 10 is formed at the free end 9A of each of the rivet pins 9, which presses the parts of the device 1 together in regions around the rivet pins 9. On the other hand, the rivet pins 9 are compressed and thus nestle against the walls of the through-holes. In this manner, the parts of the devices 1 are firmly, immovably and outwardly tightly connected to one another.

### LIST OF REFERENCE NUMERALS

1 electric or electronic device
2 housing
3 circuit board
4 shielding plate
5 housing lower part
6 housing upper part
8 mounting lug
9 rivet pin
9A free end of the rivet pin
10 rivet head
11 socket

The above description is that of current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A housing for an electric or electronic device, comprising:
a housing lower part, the housing lower part being metal and being configured as a heat sink for dissipating heat generated by the electric or electronic device, wherein at least two rivet pins are formed integrally with the housing lower part;
a circuit board, on which the electric or electronic device is formed in the form of electric or electronic components and conductive traces, the circuit board being mounted in the housing lower part;
a shielding plate for shielding electromagnetic radiation; and
a housing upper part for closing the housing, wherein the housing lower part, the circuit board, the shielding plate, and the housing upper part are connected to each another in a sealing manner by forming rivet heads on the rivet pins.

2. The housing according to claim 1, wherein the at least two rivet pins are each configured as a hollow pin with a closed upper end.

3. The housing according to claim 1, wherein the at least two rivet pins have an annular cross-section with a maximum diameter of 5 mm.

4. The housing according to claim 1, wherein the housing lower part is made of an aluminum alloy.

5. The housing according to claim 1, wherein the circuit board is galvanically connected to the housing lower part and the shielding plate.

6. The housing according to claim 1, wherein the at least two rivet pins are formed by deep drawing and extrusion.
